(19) United States
(12) Patent Application Publication
(10) Pub. No.: US 2006/0060863 A1
(43) Pub. Date: Mar. 23, 2006

(54) System and method for controlling nanostructure growth

(76) Inventors: Jennifer Lu, Milpitas, CA (US); Nicolas J. Moll, Woodside, CA (US); Thomas E. Kopley, La Honda, CA (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/946,753

(22) Filed: Sep. 22, 2004

(51) Int. Cl. H01L 29/15; H01L 31/0312

(52) U.S. Cl. 257/77; 438/931; 257/678

(57) ABSTRACT

Systems and methods are provided for controllably growing nanostructures, such as nanotubes, on a substrate, thus enabling the length and/or orientation of the nanostructures to be selectively controlled. A substrate's surface is selectively patterned to include topological structures, such as a blocking structure protruding from the surface and/or a recess in the surface, for influencing the nanostructure growth along the surface from a catalyst. The topological structures can be located to control the length and/or orientation of the nanostructures differently on different areas of the substrate. The topological structures may be of a substance that chemically inhibits growth of the nanostructure.

### BACKGROUND OF THE INVENTION

Carbon nanotubes (CNTs) have become the most studied structures in the field of nanotechnology due to their remarkable electrical, thermal, and mechanical properties. In general, a carbon nanotube can be visualized as a sheet of hexagonal graph paper rolled up into a seamless tube and joined. Each line on the graph paper represents a carbon-carbon bond, and each intersection point represents a carbon atom. In general, CNTs are elongated tubular bodies which are typically only a few atoms in circumference. The CNTs are hollow and have a linear fullerene structure. Such elongated fullerenes having diameters as small as 0.4 nanometers (nm) (Nature (408), pgs. 50-51, November 2000) and lengths of several micrometers to tens of millimeters have been recognized. Both single-walled carbon nanotubes (SWCNTs) and multi-walled carbon nanotubes (MWCNTs) have been recognized.

CNTs have been proposed for a number of applications because they possess a very desirable and unique combination of physical properties relating to, for example, strength and weight ratio. For instance, CNTs are being considered for a large number of applications, including without limitation field-emitter tips for displays, transistors, interconnect and memory elements in integrated circuits, scan tips for atomic force microscopy, and sensor elements for chemical and biological sensing. CNTs are either conductors (metallic) or semiconductors, depending on their diameter and the spiral alignment of the hexagonal rings of graphite along the tube axis. They also have very high tensile strengths. See Dresselhaus, M. S.; Dresselhaus, G., Eds. Carbon Nanotubes: Synthesis, Structure, Properties, and Applications; Springer: New York, 2001; Vol. 80. CNTs have demonstrated excellent electrical conductivity. See e.g. Yakobson, B. I., et al., American Scientist, 85, (1997), 324-337; and Dresselhaus, M. S., et al., Science of Fullerenes and Carbon Nanotubes, 1996, San Diego: Academic Press, pp. 902-905. For example, CNTs conduct heat and electricity better than copper or gold and have 100 times the tensile strength of steel, with only one-sixth of the weight of steel.

Various techniques for producing CNTs have been developed. The early processes used for CNT production were laser ablation and an arc discharge approach. More recently, chemical vapor deposition (CVD) is becoming widely used for growing CNTs. In this approach, a feedstock, such as CO or a hydrocarbon or alcohol, is heated (e.g., to 600-1000° C.) with a transition metal catalyst to promote the CNT growth. Even more recently, plasma enhanced CVD (PECVD) has been proposed for use in producing CNTs, which may permit their growth at lower temperatures, see e.g, Meyyappan, M. et al., “Carbon nanotube growth by PECVD: a review,” Plasma Sources Sci. Technology 12 (2003), pg. 205-216. Thus, in several production processes, such as CVD and PECVD, CNTs can be grown from a catalyst on a substrate surface, such as a substrate (e.g., silicon or quartz) that is suitable for fabrication of electronic devices, sensors, field emitters and other applications. For instance, using techniques as CVD and PECVD, CNTs can be grown on a substrate (e.g., wafer) that may be used in known semiconductor fabrication processes.

Key to many applications is the control of CNT length and/or placement (position and orientation). Handling of CNTs is generally cumbersome, resulting in difficulty in post-processing of CNTs (after they are grown) to control/modify their lengths and/or placement. Accordingly, interest has arisen in controlling the growth of CNTs (e.g., to avoid, minimize, or at least ease the post-processing of CNTs to arrive at desired lengths and/or placement).

### BRIEF SUMMARY OF THE INVENTION

In view of the above, a desire exists for a system and method for controlling the growth of nanotubes on a substrate surface. More particularly, a desire exists for a system and method for controlling the growth of nanotubes on a substrate surface to control the resulting length and/or orientation of the nanotubes. Preferably, such a technique would be practical for use in a manufacturing environment, such as a technique that can be easily integrated within known semiconductor fabrication processes. Also, the technique would preferably enable selective control of the growth of nanotubes over different areas (“regions”) of a substrate, wherein the length and/or orientation of nanotubes controllably differ over the different areas of a substrate.

Novel systems and methods are provided herein for controllably growing nanostructures, such as nanotubes, on a substrate, thus enabling the length and/or orientation of the nanotubes to be selectively controlled. According to various embodiments provided herein, a surface of a substrate may be selectively patterned to influence the growth of nanostructures from at least one catalyst along the substrate surface. For example, in certain embodiments, a substrate is selectively patterned to influence length and/or orientation of nanotubes grown from a catalyst along the surface of the substrate. Thus, one or more catalysts for growth of nanotubes may be located on a substrate having patterned features, wherein the patterned features influence the growth of the nanotubes along the substrate's surface (e.g., influence the length and/or orientation of the nanotubes). Accordingly, a topological structure formed on the substrate provides a growth control structure that influences, during the growth process, at least one of length and orientation of the nanotubes.

As described further herein, the patterned features can be selectively arranged to influence the length and/or orientation of the nanotubes differently on different areas of the substrate. The patterned features are selectively arranged on the substrate to provide a solid barrier for influencing the growth of nanotubes through physical contact between the patterned features and the nanotubes, as opposed to (or in addition to) use of such known techniques as application of electric fields (either external to or arranged locally on the substrate), application of magnetic fields, blowing gas in a certain direction, a directed ion stream, control of carbon gas density gradient during growth (which may influence in what direction the tubes grow, i.e., they should grow along the carbon gradient). Thus, the patterned features implemented on the substrate in the embodiments described herein provide a solid-barrier means versus a fluid (liquid or gas) or force-field means. In certain embodiments, the patterned features also provide chemical control over the growth of the nanotubes by forming such patterned features of a substance known to chemically inhibit further growth of nanotubes. Further, the application of patterned features in accordance with various embodiments integrates easily with known manufacturing processes, such as known semiconductor fabrication processes.

In addition to CNTs, other types of nanotubes have been developed, including boron nitride nanotubes, and silicate-based nanotubes. Except where the accompanying language specifies otherwise, the term “nanotubes” is used herein generally to encompass any type of nanotube structure now known or later developed. Thus, while embodiments hereof have particular applicability for use in controlling the growth of CNTs (which may be SWCNTs or MWCNTs), various embodiments may be similarly used for controlling the growth of other nanotube structures, such as boron nitride nanotubes and silicate-based nanotubes, that may be grown on a substrate surface in a manner similar to that described herein. Additionally, this concept is not limited in application to controlling the growth of nanotubes, but may likewise be utilized for controlling the growth of other nanostructures (particularly those having high aspect ratios), such as nanofibers, nanoribbons, nanothreads, nanowires, nanorods, nanobelts, nanosheets, nanorings, polymers, and biomolecules, as examples.

### BRIEF DESCRIPTION OF THE DRAWINGS

FIGS. 1A-1B show an example of one embodiment of a substrate having a topological structure for controlling growth of CNTs;

FIGS. 2A-2B show the example substrate of FIGS. 1A-1B having CNTs grown thereon;

FIGS. 3A-3B show an example of another embodiment of a substrate having a topological structure for controlling growth of CNTs;

FIGS. 4A-4B show an example of another embodiment of a substrate having a topological structure for controlling growth of CNTs;

FIG. 5 shows an exemplary embodiment of a substrate having topological structures for controlling growth of CNTs, wherein the topological structures control the orientation of the CNTs on the substrate;

FIG. 6 shows another exemplary embodiment of a substrate having topological structures for controlling growth of CNTs, wherein the topological structures control the orientation of the CNTs on the substrate;

FIGS. 7A-7B show an example in which an additional layer of controllably grown CNTs is provided over the resulting layer of CNTs from FIG. 6; and

FIG. 8 shows an operational flow diagram according to one embodiment for controlling growth of nanotubes.

### DETAILED DESCRIPTION OF THE INVENTION

According to various embodiments provided herein, a topological structure is located on the surface of a substrate for controlling the growth of nanotubes along the substrate's surface. Such topological structure may include a raised structure protruding from the substrate's surface and/or a trench in the substrate's surface. For instance, the surface of a substrate may be selectively patterned to form the topological structure(s) for controlling the growth of nanotubes from at least one catalyst along the substrate surface. For example, in certain embodiments, a substrate is selectively patterned to control length and/or orientation of nanotubes grown from a catalyst along the surface of the substrate. Thus, one or more catalyst regions for growth of nanotubes may be located on a substrate having topological structures formed thereon, wherein the topological structures control the growth of the nanotubes along the substrate's surface (e.g., control the length and/or orientation of the nanotubes). As described further herein, the topological structures can be selectively arranged to control the length and/or orientation of the nanotubes differently on different areas of the substrate.

When referring to “controlling” the growth of nanotubes with topological structures herein, it should be appreciated that such topological structures may not fully control the nanotubes. For example, the nanotubes may initially grow in random directions from the catalyst. Alternatively, some other element, such as an electric field, etc., may be used to control the direction of growth from the catalyst. The topological structures provide control over the growth of nanotubes by influencing the growth (e.g., terminating the growth, re-directing the growth, etc.) of those nanotubes that encounter the topological structures.

The topological structures of certain embodiments provide mechanical control (through physical contact between the topological structures and the nanotubes), or mechanical control assisted by chemical means such as poisoning the catalyst in the case of tip growth, over the growth of the nanotubes. The topological structures are selectively located on the substrate to provide a solid barrier for influencing the growth of nanotubes through physical contact between the topological structures and the nanotubes, as opposed to (or in addition to) use of such known techniques as application of electric fields (either external to or arranged locally on the substrate), application of magnetic fields, blowing gas in a certain direction, a directed ion stream, control of carbon gas density gradient during growth (which may influence in what direction the tubes grow, i.e., they should grow along the carbon gradient).

Embodiments described herein use topological structures that are selectively arranged on the substrate to provide a solid barrier for influencing the growth of nanotubes through physical contact between the patterned features and the nanotubes, as opposed to (or in addition to) the above-mentioned techniques. The term “solid barrier” herein is not intended to be limited to blocking structures that protrude from the substrate surface, but is intended also to encompass other types of terrain features, such as trenches implemented in the substrate surface. Thus, the topological structures implemented on the substrate in the embodiments described herein provide a solid-barrier means versus a fluid (liquid or gas) or force-field means. Thus, the topological structures adapt the terrain of the substrate's surface to influence the growth of nanotubes along the surface through physical contact between the topological structures (or “solid-barrier means”) and the growing nanotubes instead of or in addition to use of other techniques for influencing nanotube growth that do not involve physical contact between topological structures on the substrate and the nanotubes, such as the techniques that apply a force from a force field or a flowing fluid or both.

Further, as described below, the application of such topological structures in accordance with various embodiments integrates easily with known manufacturing processes, such as known semiconductor fabrication processes. For instance, the patterned features may be selectively formed on a substrate using known lithography techniques to result in the desired topological structures.

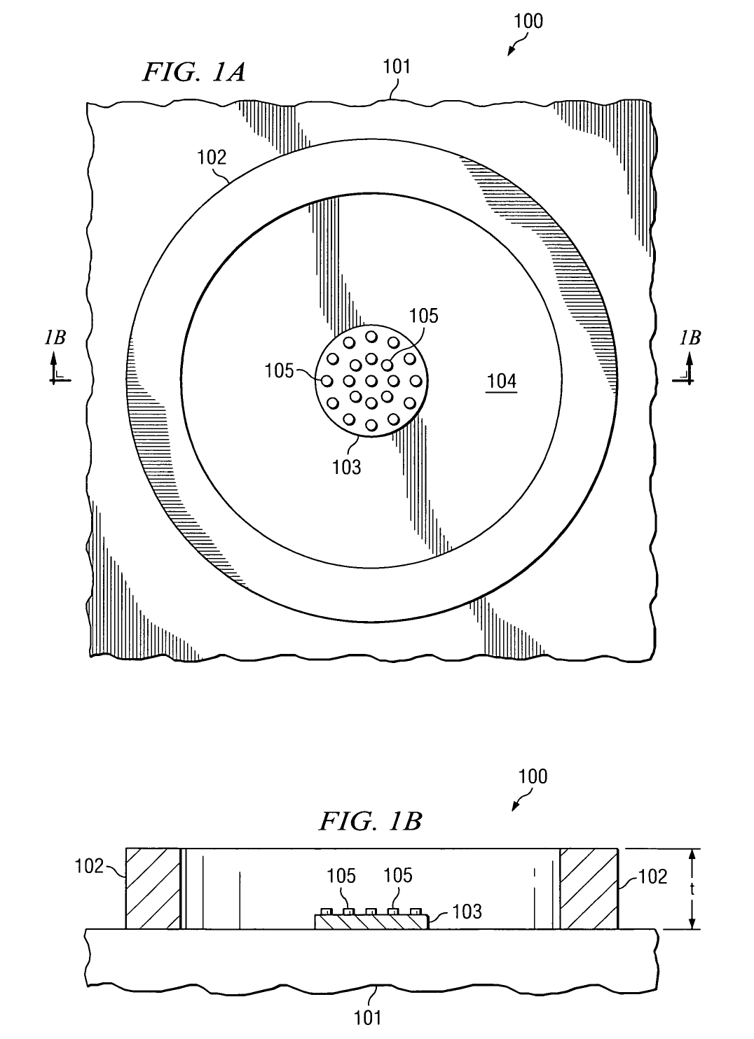

Turning to FIGS. 1A-1B, an example of one embodiment of a topological structure (which in this example is formed via patterning a substrate) for controlling growth of CNTs is shown. FIG. 1A is a plan view of the surface of a substrate 101, while FIG. 1B is a view of the cross-section indicated in FIG. 1A. The exemplary system 100 illustrated in FIGS. 1A-1B includes substrate 101 having topological structure 102. Substrate 101 is, in one embodiment, a material commonly used for substrates in semiconductor fabrication processes, such as silicon with a layer of thermally-grown SiO₂ on its major surface, for example. In this example, topological structure 102 is a raised structure from the surface of substrate 101, wherein topological structure 102 forms an annulus. Such raised structure may be formed using known semiconductor fabrication techniques in which material (e.g., silicon) is deposited on the surface of substrate 101 and is patterned to form such annulus. As one example, topological structure 102 may be a thin film patterned into an annulus using standard microlithographic techniques. Topological structure 102 is of a material capable of withstanding the CNT growth process. For instance, temperatures of 600-1000° C. are typically used for growing CNTs, and thus such material used for forming topological structure 102 is capable of withstanding the temperature used in the growth process. Exemplary materials capable of withstanding the typical growth temperatures include SiO₂, Al₂O₃, polysilicon, and some refractory metals. Particularly if the CNT growth mechanism is via tip growth, it may be advantageous to use a material that is known to chemically inhibit the CNT catalytic reaction, such as silicon or polysilicon, as the material of topological structure 102.

A catalyst region 103 for growing CNTs is also included on substrate 101. In this example, the catalyst region is located substantially in the center of the growth field 104 defined by topological structure 102. Catalyst region 103 includes materials for growing CNTs, such as iron, cobalt, or nickel, or alloys thereof, nanoparticles on a supporting material such as alumina (Al₂O₃), porous silica, or MgO, as examples, or any other suitable material now known or later developed for use in growing CNTs (or other desired nanotube structures, such as use of FeB nanoparticles as the catalyst for boron nitride nanotube growth). Such catalyst region 103 may be spun-on the substrate and patterned into a smaller region within the annulus. While the catalyst region 103 is shown as circular in this example, it may be patterned into other desired shapes in alternative implementations. Additionally, although catalyst region 103 is located in one location on substrate 101 in this example, in other applications such catalyst region 103 may be selectively placed on various locations of substrate 101. Exemplary catalyst nanoparticles 105 from which individual nanotubes may grow are illustrated in catalyst region 103, and it should be recognized that for ease of illustration these nanoparticles 105 (as well as other elements of the FIGURES) are not drawn to scale.

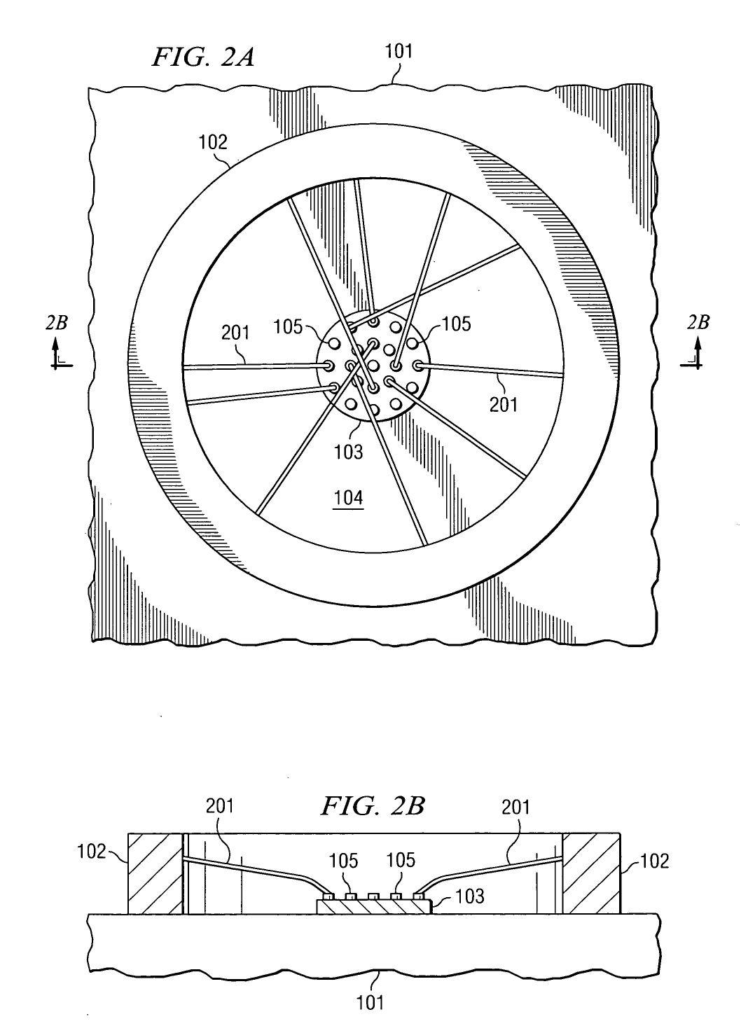

As shown in FIGS. 2A-2B, nanotubes grow outward from the catalyst region 103 in the circular growth field 104 defined by topological structure 102. The topological structure 102 inhibits the growth of CNTs along the surface of substrate 101 beyond the perimeter established by such topological structure 102, thereby controlling the resulting length of the CNTs grown along the surface of the substrate 101 from catalyst region 103. For instance, FIGS. 2A-2B show the system 100 of FIGS. 1A-1B after a period of growth of CNTs from catalyst region 103. FIG. 2A is a plan view of the surface of a substrate 101 (corresponding to that of FIG. 1A), while FIG. 2B is a view of the cross-section indicated in FIG. 2A (corresponding to the cross-section of FIG. 1B). In this example, an annular topological structure 102 is shown, but as described further herein, topological structures with various other shapes may be used instead of or in addition to the topological structure shown in this example for influencing the growth of nanotubes as desired.

As shown in FIGS. 2A-2B, CNTs 201 are grown from catalyst region 103 using techniques now known or later developed, such as CVD, PECVD, or other techniques for growing nanotubes on a substrate. During CNT growth, the nanotubes grow from the catalyst region 103 radially outward until they contact the surrounding topological structure 102 at which point they stop lengthening.

Because the topological structure 102 inhibits the growth of CNTs 201 that are growing substantially along the surface of substrate 101, the length of such CNTs 201 growing substantially along the surface of substrate 101 is controlled. As shown in FIG. 2B, the CNTs 201 may not actually be in contact with the surface of substrate 101, but may instead be growing along the surface at some distance above the substrate surface. As long as a CNT 201 does not grow upward from the surface of substrate 101 to a height above the height “t” of topological structure 102 by the time in the growth process that the CNT reaches the topological structure 102, such topological structure 102 will mechanically (or mechanically and chemically) inhibit further growth of the CNT beyond growth field 104. In this example, catalyst region 103 is located substantially in the center of growth field 104 defined by topological structure 102, thus resulting in CNTs 201 having substantially the same lengths, each roughly equal to the radius of growth field 104 formed by the topological structure 102.

The topological structure 102 may be referred to as a “blocking structure” in this example because it protrudes from the surface of substrate 101 and blocks the growth of CNTs along the substrate's surface from progressing beyond the perimeter of growth field 104 established by such blocking structure. Thus, topological structure 102 provides an annular wall, the inner surface of which (relative to catalyst region 103) defines a growth field 104 in which CNTs can grow from catalyst region 103.

The catalyst region 103 can be spun onto the substrate. The spun-on catalyst region carries the catalyst particles 105, and the spun-on catalyst region is typically mostly polymer and is much thicker than the size of individual catalyst particles 105. For instance, the spun-on catalyst region is typically approximately 20 nm thick, while the size of individual catalyst particles 105 is approximately 1.5 to 4 nm thick. The final catalyst region 103 may be a layer that is thinner than the layer spun-on originally, depending on the subsequent process steps that prepare the catalyst nanoparticles 105 for growth. For instance, in many cases the catalyst region 103 is approximately 2 nm thick after it is spun-on and processed (e.g., the processing in certain embodiments removes the organic components from the spun-on catalyst region). In general, a blocking structure having a thickness t>3 nm or so exceeds the diameter of a typical nanotube, and in practice a blocking structure having thickness t>20 nm has been sufficient for blocking the nanotubes growing from the catalyst region. Of course, any thickness “t” that is sufficient for blocking the nanotubes as desired in a given application may be employed. The catalyst region 103 may be patterned into a desired shape. The issue of the patterned blocking structure interfering with the spun-on layer can be avoided by spinning on and patterning the catalyst region 103 before depositing the blocking structure.

Further, as mentioned above, in certain embodiments, the material of the topological structure 102 may be a substance (e.g., silicon or polysilicon) that chemically inhibits further growth of the CNTs 201 once it is contacted, while in other embodiments mechanical engagement of the CNTs with such topological structure 102 may be solely relied upon to mechanically inhibit further growth of the CNTs 201. An example of mechanical contact between CNTs 201 and topological structure 102 is described above with reference to FIGS. 2A-2B. Again, in certain embodiments, such topological structure 102 may be of a material that chemically inhibits further growth of CNTs 201 that come into contact with the topological structure 102, while in other embodiments mechanical contact alone may be relied upon for influencing the growth of the CNTs 201.

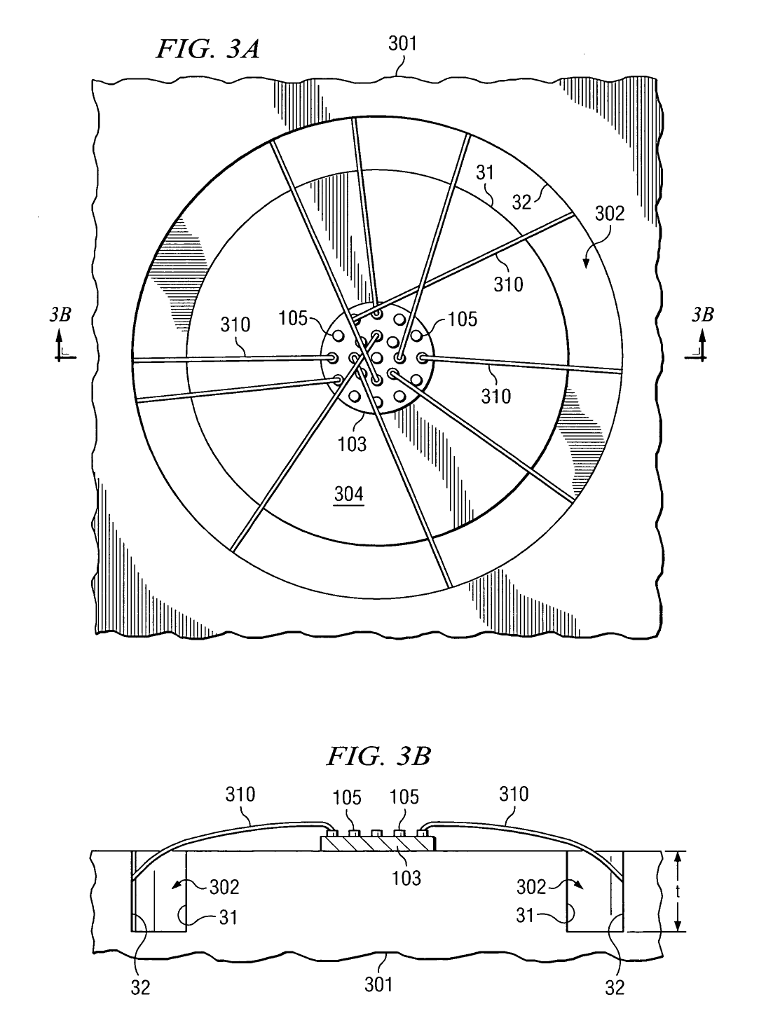

While the topological structure 102 is formed through deposition of material onto the surface of substrate 101 (e.g., to form a “blocking structure”) in the exemplary embodiment of FIGS. 1A-1B and 2A-2B, in other embodiments the topological structure used for controlling growth of CNTs may be formed in some other manner. For instance, FIGS. 3A-3B show another exemplary embodiment of a topological structure for controlling growth of CNTs. FIG. 3A is a plan view of the surface of a substrate 301, while FIG. 3B is a view of the cross-section indicated in FIG. 3A. The exemplary system illustrated in FIGS. 3A-3B includes substrate 301 having topological structure 302, which in this example is a trench etched into the surface of substrate 301. Topological structure 302 is patterned in the shape of a circle, as with topological structure 102 described above. Such trench structure may be formed using known semiconductor fabrication techniques for selectively etching the surface of substrate 301 in such circular pattern. Catalyst region 103 for growing CNTs (analogous to catalyst region 103 described above) is also included on substrate 301, which is located substantially in the center of the circular growth field 304 formed by topological structure 302. Thus, topological structure 302 provides an annular trench, the outer wall of which (wall 32) defines a growth field 304 in which CNTs can grow from catalyst region 103.

As shown, the topological structure 302 inhibits the growth of CNTs along the surface of substrate 301 beyond the perimeter of growth field 304 established by such topological structure 302, thereby controlling the resulting length of the CNTs grown along the surface of the substrate 301 from catalyst region 103. For instance, after a period of growth of CNTs from catalyst region 103, CNTs 310 are grown from catalyst region 103. Because the topological structure 302 inhibits the growth of CNTs 310 that are growing substantially along the surface of substrate 301, the length of such CNTs 310 growing substantially along the surface of substrate 301 is controlled. As with the example of FIGS. 1A-1B and 2A-2B, catalyst region 103 is located substantially in the center of the growth field 304 defined by topological structure 302 in this example of FIGS. 3A-3B, thus resulting in CNTs 310 having substantially the same lengths, each roughly equal to the radius of growth field 304.

The trench of topological structure 302 includes an inner wall 31 (relative to the catalyst region 103) and an outer wall 32. The trench has a depth “t,” which may be any depth that is determined to be sufficient to cause a nanotube that grows to the trench to engage the outer wall 32. As shown in FIG. 3B, as CNTs 310 grow from catalyst region 103 such that when their distal ends lengthen beyond the inner wall 31 of topological structure 302 (trench), the distal ends dip into the trench and engage outer wall 32. Engagement of the distal ends with the outer wall inhibits further growth beyond the perimeter of growth field 304 established by such outer wall 32. In certain embodiments, mechanical engagement of the CNTs with such wall 32 of topological structure 302 may be solely relied upon to mechanically inhibit further growth of the CNTs 310. In certain embodiments, the topological structure 302 may be of a material that chemically inhibits further growth of the CNTs once it is contacted. For instance, the outer wall 32 may be of a substance known to chemically inhibit further growth of CNTs, such as silicon or polysilicon.

As with the examples of FIGS. 1A-1B and 2A-2B, while the topological structure 302 is shown in FIGS. 3A-3B as a circular ring within which catalyst region 103 is located, such topological structure may define a growth field with any desired shape/pattern in alternative embodiments. Further, while the catalyst region 103 is shown as circular in this example, it may be patterned into other desired shapes in alternative implementations. Additionally, although catalyst region 103 is located in one location on substrate 301 in this example, in other applications such catalyst region 103 may be selectively located at more than one location on substrate 301. Thus, for instance, the catalyst region 103 may be located on the substrate in a desired relationship with the topological structure 302 such that the topological structure 302 influences the growth of CNTs from catalyst region 103 in a desired manner.

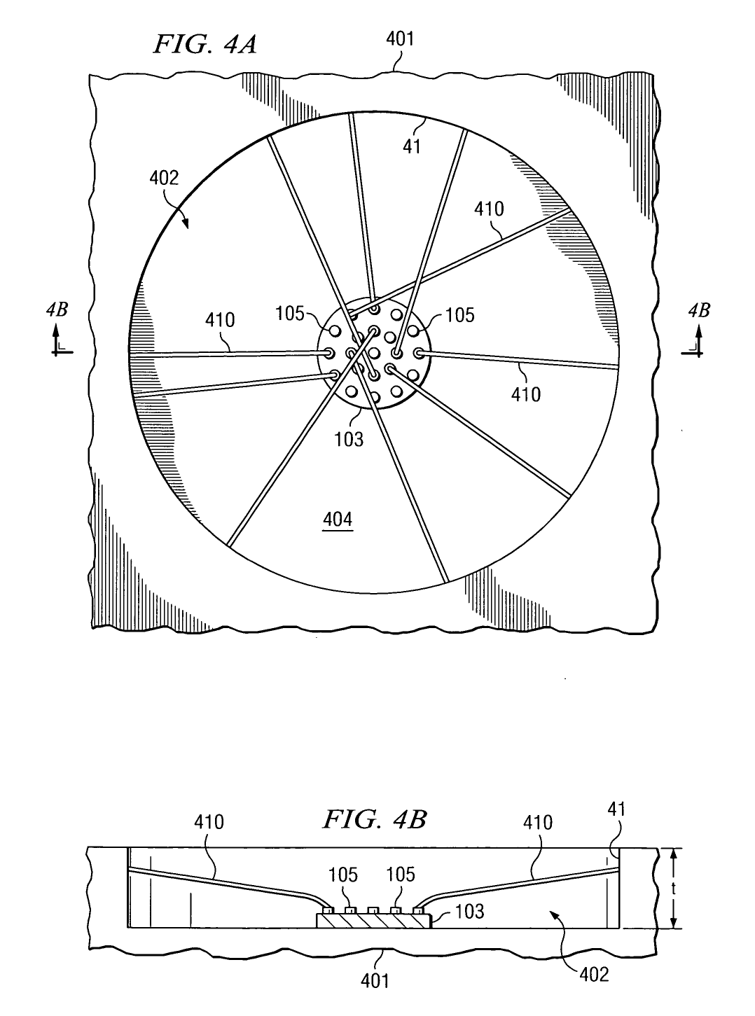

FIGS. 4A-4B show yet another exemplary embodiment of a patterned substrate for controlling growth of CNTs. FIG. 4A is a plan view of the surface of a substrate 401, while FIG. 4B is a view of the cross-section indicated in FIG. 4A. The exemplary system illustrated in FIGS. 4A-4B includes substrate 401 having topological structure 402, which in this example is a recess etched into substrate 401 from the surface. The recess is circular in shape and is bounded by perimeter wall 41. Such topological structure 402 may be formed using known semiconductor fabrication techniques for selectively etching such circular pattern into the surface of substrate 401. Catalyst region 103 for growing CNTs (analogous to catalyst region 103 described above) is located substantially in the center of topological structure 402. Thus, topological structure 402 defines a growth field 404 in which CNTs can grow from catalyst region 103.

As shown, the topological structure 402 (particularly perimeter wall 41) inhibits the growth of CNTs along the surface of substrate 401 beyond the perimeter of growth field 404 established by such topological structure 402, thereby controlling the resulting length of the CNTs grown along the surface of the substrate 401 from catalyst region 103. In this example, the CNTs grown along the surface of the substrate within the growth field 404 defined by topological structure 402 have their length restricted by the perimeter wall 41. For instance, after a period of growth of CNTs from catalyst region 103, CNTs 410 are grown from catalyst region 103. Because the topological structure 402 (particularly the perimeter wall 41) inhibits the growth of CNTs 410 that are growing substantially along the surface of substrate 401 within growth field 404, the length of such CNTs 410 growing substantially along the surface of substrate 401 is controlled. As with the example of FIGS. 1A-1B, 2A-2B, and 3A-3B, catalyst region 103 is located substantially in the center of the circular growth field 404 defined by topological structure 402 in this example of FIGS. 4A-4B, thus resulting in CNTs 410 having substantially the same lengths, each roughly equal to the radius of the perimeter wall 41 that forms part of the topological structure 402. It should be recognized that FIGS. 4A-4B essentially illustrate that the blocking structures of FIGS. 1A-1B and 2A-2B that are shown as topological structure 102 may be arrived at through etching a recess bounded by a perimeter wall 41, rather than depositing a surrounding topological structure 102. Thus, perimeter wall 41 in FIGS. 4A-4B acts in the same blocking manner as the raised topological structure 102 in FIGS. 1A-1B and 2A-2B.

The recess of topological structure 402, in this example, has a depth “t” which may be determined as with the height “t” described above in conjunction with FIG. 1B. In certain embodiments, the topological structure may be composed of a substance that chemically inhibits further growth of the CNTs once it is contacted. For instance, the perimeter wall 41 may be of a substance known to chemically inhibit further growth of CNTs, such as silicon or polysilicon. In other embodiments, mechanical engagement of the CNTs with such perimeter wall 41 of topological structure 402 may be solely relied upon to mechanically inhibit further growth of the CNTs 410.

As with the examples of FIGS. 1A-1B, 2A-2B and 3A-3B, while the topological structure 402 is shown in FIGS. 4A-4B as defining a circular growth field 404 within which catalyst region 103 is located, such topological structure may define a growth field with any desired shape/pattern in alternative embodiments. Further, while the catalyst region 103 is shown as circular in this example, it may be patterned into other desired shapes in alternative implementations. Additionally, although catalyst region 103 is located in one location on substrate 401 in this example, in other applications such catalyst region 103 may be selectively located at more than one location on substrate 401.

While the catalyst region is substantially centered in the exemplary circular growth fields shown in FIGS. 1A-1B, 2A-2B, 3A-3B, and 4A-4B, in other embodiments the catalyst region may be located off center. In such an off-center implementation, the CNTs grown in the direction toward the circumference of the growth field that is nearer the catalyst region will be shorter than those grown in the direction toward the growth field's circumference that is further from the catalyst region. Thus, while all CNTs grown in this manner will not have substantially the same length, the relative lengths of the CNTs grown in the different directions are still controlled. It may be desirable for certain applications for the CNTs that grow from the catalyst region along the substrate surface in different directions to have different lengths in this manner.

While the CNTs are shown in the above examples of FIGS. 2A-2B, 3A-3B, 4A-4B, and 9 as growing in all directions, certain techniques may be further utilized to direct the CNT growth in a particular direction. For instance, force-field and/or fluid flow techniques may be used during growth of the CNTs. Such techniques include application of electric fields (either external to or arranged locally on the substrate), application of magnetic fields, blowing gas in a certain direction, etc. in order to direct the direction of the growth. Thus, the topological structures described herein may be used in conjunction with other growth control techniques, such as the above-mentioned techniques for controlling the direction of CNT growth.

In view of the above, various embodiments utilize topological structures on a substrate (e.g., patterned thin film layers or walls defined in a substrate) to define regions where CNT growth is permitted and is inhibited, thus effectively controlling the CNT length. Further, while the exemplary embodiments of FIGS. 1A-1B, 2A-2B, 3A-3B, and 4A-4B show a circular growth field defined by a topological structure for use in controlling the growth of CNTs, such circular growth field is merely an example. Various other shapes of the growth field may be used, including without limitation square, rectangular, hexagonal, octagonal, pentagonal, etc. Further, while the topological structure fully surrounds the catalyst region in the above examples, in other embodiments the topological structure may not fully surround the catalyst region. The pattern and/or arrangement of topological structures relative to catalyst region(s) may be selected to control the lengths of the CNTs in a corresponding manner. For instance, the topological structure may be located on one or more sides of the catalyst region so as to selectively control the growth of CNTs from the catalyst region on the respective one or more sides. As one example, a topological structure (e.g., wall) may be located on only one side of the catalyst region in certain implementations and the growth process may be controlled (e.g., through use of such means as application of an electric field, blowing gas in a particular direction, etc.) to direct the growth of the CNTs toward the topological structure, which in turn controls the length of the CNTs.

Further still, in certain embodiments, different topological structures may be located on different sides of the catalyst region. For instance, a first topological structure may be located on a substrate to control the growth of nanotubes from one side of the catalyst region in one pattern and/or relationship to the catalyst region (e.g., one defining a semi-circular growth field within which the catalyst region is substantially centered such that the resulting nanotubes grown on this one side of the catalyst region have substantially the same lengths, corresponding to the radius of the growth field), and a second topological structure may be located on the opposite side of the catalyst region to control the growth of nanotubes from such opposite side of the catalyst region in a differently shaped growth field and/or one having a different relationship to the catalyst region (e.g., a partially rectangular growth field within which the catalyst region is located). In this manner, the growth of nanotubes may be controlled differently in different growth fields of the substrate, which may be desirable for certain applications.

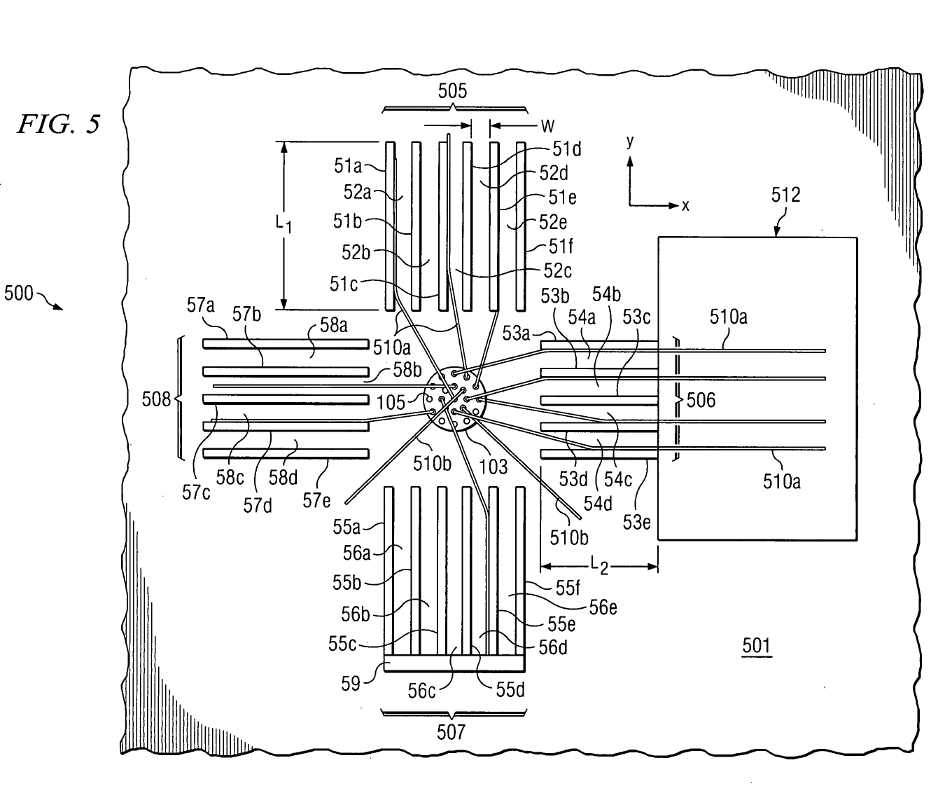

While the above exemplary embodiments use topological structures to control the length of CNTs, in other embodiments, such topological structures may be used additionally or alternatively to control the orientation of CNTs on the substrate. FIG. 5 shows an exemplary embodiment of topological structures for controlling growth of CNTs, wherein the topological structures control the orientation of the CNTs on the substrate. The exemplary system 500 illustrated in FIG. 5 includes substrate 501 having various topological structures implemented thereon. In this example, groups of parallel topological structures (e.g., walls or trenches, including trenches formed by crystallographic etches, e.g. etches of 100 silicon that stop on 111 planes, forming V-grooves in the silicon) are implemented on each of four sides of a catalyst region 103. For instance, a first group 505 of parallel topological structures (walls or trenches) 51a-51f is arranged on a first side of catalyst region 103 (e.g., on the positive “Y” side of catalyst region 103) and effectively forms channels 52a-52e in which CNTs grow as described further below. A second group 506 of parallel topological structures (walls or trenches) 53a-53e is arranged on a second side of catalyst region 103 (e.g., on the positive “X” side of catalyst region 103) and effectively forms channels 54a-54d in which CNTs grow as described further below. A third group 507 of parallel topological structures (walls or trenches) 55a-55f is arranged on a third side of catalyst region 103 (e.g., on the negative “Y” side of catalyst region 103) and effectively forms channels 56a-56e in which CNTs grow as described further below. And, a fourth group 508 of parallel topological structures (walls or trenches) 57a-57e is arranged on a fourth side of catalyst region 103 (e.g., on the negative “X” side of catalyst region 103) and effectively forms channels 58a-58d in which CNTs grow as described further below.

In this example, the parallel topological structures are arranged to form channels in which CNTs grow, wherein the topological structures thus control the orientation of CNTs growing along the surface of the substrate 501. For instance, as CNTs 510 grow from catalyst region 103, certain CNTs (510a) grow into a channel formed between two of the topological structures. The two topological structures direct the growth of such CNTs 510a along their respective channel. Other CNTs (510b) that do not grow into a channel are shown in this example as not being oriented in a controlled manner.

During CNT growth (e.g., during a CVD or PECVD growth process), the CNTs 510 grow outward from the catalyst region 103 until they contact an adjacent topological structure, at which point they either stop lengthening or continue growing along the topological structure's edge. That is, depending on the angle at which the CNT engages the topological structure, the topological structure may redirect the CNT's growth along the topological structure's edge. If a CNT contacts a topological structure at a contact angle within any of a certain range of contact angles, the growth of the CNT is re-directed, rather than terminated. For instance, if the contact angle is approximately 90 degrees, the nanotube's growth will terminate. Alternatively, if the contact angle is a grazing angle (e.g., 1 degree), then the nanotube will be redirected by the topological structure and will keep growing. The geometries of the topological structures implemented on the substrate 103 may be devised such that the growing CNTs 510 contact the topological structure edges at angles less than an angle that would cause the CNTs to stop growing. Instead, the topological structures collectively define growth paths along which the CNTs grow.

As one example, force-field and/or fluid flow techniques, such as application of an electric field, etc., may be employed to control the direction in which the nanotubes grow from the catalyst region, and the topological structures may be selectively arranged on the substrate in relation to the catalyst region such that at least a portion of the nanotubes are likely to contact the topological structures at an angle within a desired range of angles. As another example, a first set of topological structures may be implemented close to the catalyst region and a second set of topological structures may be implemented further away from the catalyst region. The first set of topological structures may be arranged to block the growth of nanotubes except those growing within a given range of angles relative the second set of topological structures. In this manner, the nanotubes that reach the second set of topological structures are known to be growing within a desired range of angles relative to those second set of topological structures.

The parallel topological structures of group 505, for example, controls the orientation and number of CNTs 510 in the corresponding region of the substrate 501. While the topological structures are shown in this example as straight, parallel lines, it is possible for the topological structures to define more complicated paths for the CNTs to follow during their growth depending on the desired application. For example, topological structures may be arranged to define zig-zag or loop growth paths, instead of the straight-line growth paths exemplified. Further, in certain implementations, such as that of the parallel topological structures of group 505 of FIG. 5, the topological structures need not extend for the entire desired length of the CNTs. Rather, the topological structures may capture the CNTs and orient them along the correct growth path, and, so long as no other structure (or other impediment) is encountered, the CNTs will continue to grow along such growth path (even beyond the extent of the topological structures). For some applications, it may be desirable to grow parallel suspended CNTs. In this case, the topological structure can be terminated next to a shallow etched recess, such as the recess 512 etched in substrate 501 at which the parallel topological structures of group 506 terminate, wherein the CNTs 510a growing in the growth paths defined by the parallel topological structures of group 506 grow further as cantilevers over the recess 512. It is also possible for CNTs 510a to grow over the edge of the substrate 501 in certain embodiments, if so desired.

The width of the growth paths, such as the width “W” of growth path 52d in FIG. 5, may be selected to encourage or discourage the growth of more than one nanotube within a given growth path. In certain implementations, it may be desirable to have one nanotube per growth path, and thus, it may be desirable to have a very narrow growth path. The width of the growth path is defined by the patterning technique used for creating the topological structures on the substrate, for example. The smallest width obtainable may be limited by the minimum feature size obtainable by the corresponding patterning technique utilized for forming the topological structures. For instance, optical lithography may enable a width of a line (of a pattern) of approximately 100 nm to 1000 nm, while E-beam lithography is currently down to 50 nm.

Further, the lengths of the various sets of topological structures need not be the same. For instance, the length L₁ of set 505 is longer than the length L₂ of set 506 in the example of FIG. 5. Further, the length of the topological structures need not be the full length desired for the nanotubes. Rather, the topological structures may just be sufficiently long that nanotube(s) that physically contact such topological structures are re-directed. The re-directed nanotube(s) then continue to grow in the desired direction unless/until another structure changes the growth of the nanotube(s) otherwise.

Additionally, in some applications the topological structures control both the orientation and the length of the CNTs. For instance, terminating topological structure 59 (e.g., wall or trench) is located at the end of the growth path defined by the parallel topological structures of group 507. Thus, both the orientation and the length of the CNTs 510a captured by group 507 of parallel topological structures is controlled.

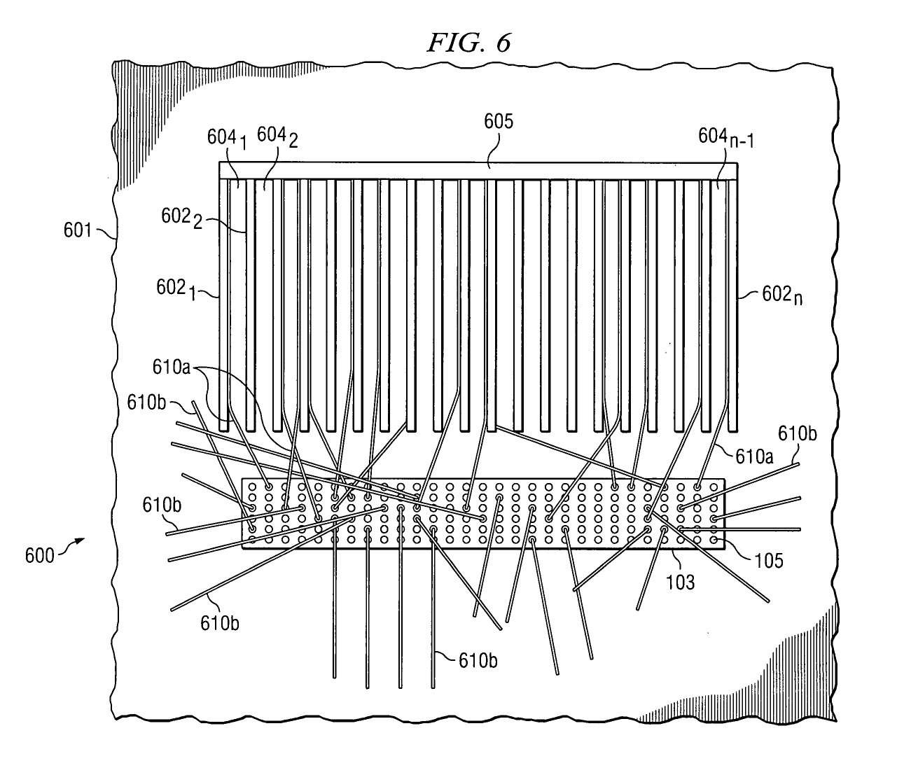

Additionally, a larger and/or patterned catalyst region may be used in certain embodiments. That is, the size and/or pattern of the catalyst region may be selected to complement the size and shape of the topological structures located on a substrate. For instance, a long rectangular catalyst region could be used to make a long array of parallel CNTs, such as shown in the example of FIG. 6. In system 600 of FIG. 6, substrate 601 includes long, rectangular catalyst region 103 located thereon. On one side of such catalyst region 103, parallel topological structures (e.g., walls or trenches) 602₁-602ₙ each oriented orthogonally to the length of catalyst region 103 are implemented, thus forming growth paths 604₁-604ₙ₋₁ in which CNTs growing along the surface of substrate 601 are captured. For instance, as CNTs 610 grow from catalyst region 103, certain CNTs (610a) are captured within a growth path defined by two adjacent ones of the topological structures. The growth of such captured CNTs 610a is directed along the respective growth paths. Other CNTs (610b) that are not captured by a growth path are shown in this example as not being oriented in a controlled manner.

During CNT growth (e.g., during a CVD or PECVD growth process), the CNTs 610 grow outward from the catalyst region 103 outward until they contact an adjacent topological structure, at which point they either stop lengthening or continue growing along the topological structure's edge. That is, depending on the angle at which the CNT engages the topological structure, the topological structure may redirect the CNT's growth along the topological structure's edge. Thus, in the region of substrate 601 on which topological structures 602₁-602ₙ are implemented, the CNTs are oriented in a desired manner (e.g., parallel to each other with spacing between the nanotubes also being somewhat controlled by the width of the growth paths defined by the topological structures 604₁-604ₙ₋₁.

Additionally, in this example both the orientation and the length of the CNTs is controlled. Terminating structure 605 (e.g., wall or trench) is located at the end of the growth paths formed by the parallel topological structures 602₁-602ₙ. Thus, both the orientation and the length of the CNTs 610a captured by parallel topological structures 602₁-602ₙ is controlled as desired in the corresponding region of substrate 601.

The example of FIG. 6 also shows the density of CNTs grown from the catalyst region optimized to obtain a uniform distribution of CNTs. Too few CNTs would result in some growth paths not having any CNTs while too many CNTs would result in some growth paths having multiple CNTs. In some applications, it may be desirable or acceptable to have multiple CNTs per growth path.

While the CNTs 610 are shown in this example as growing outward in all directions from catalyst region 103, certain techniques may be further utilized to direct the CNT growth in a particular direction. For instance, force-field and/or fluid flow means may be used during growth of the CNTs, such as application of electric fields (either external to or arranged locally on the substrate), application of magnetic fields, blowing gas in a certain direction, etc. in order to direct the direction of the growth. Thus, for example, an electric field may be applied during the growth process to direct the growth of the CNTs generally from the catalyst region 103 in the direction of the topological structures 602₁-602ₙ.

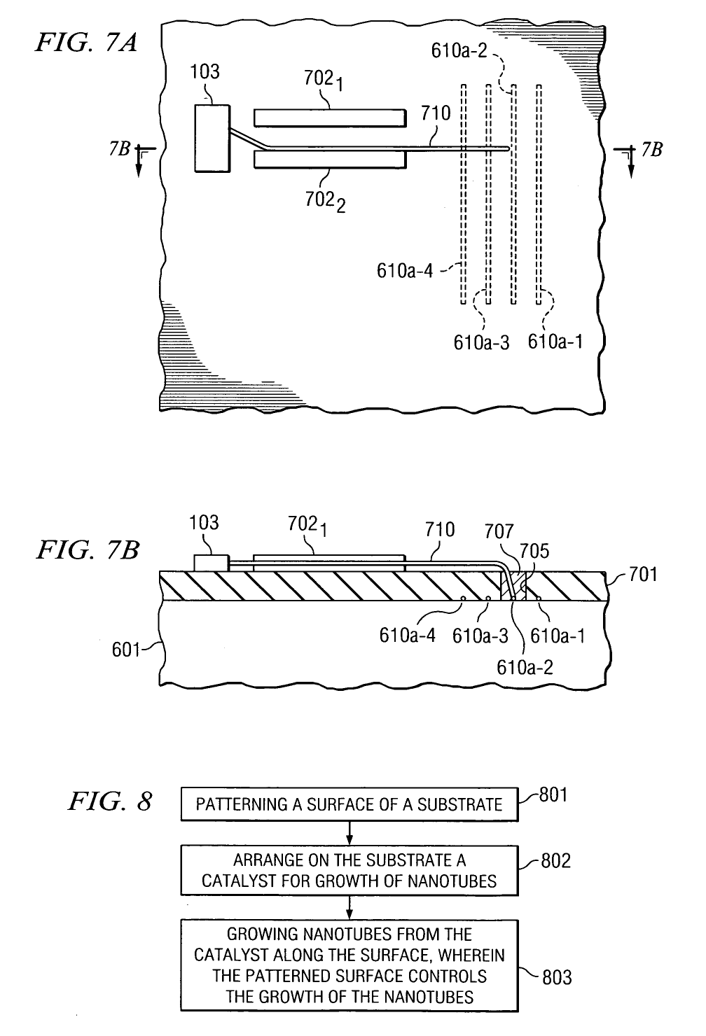

Turning now to FIGS. 7A-7B, a further exemplary application of an embodiment of the present invention is shown. FIG. 7A is a plan view of the surface of a substrate 601 (of FIG. 6), while FIG. 7B is a view of the cross-section indicated in FIG. 7A. This example illustrates that two layers of CNTs may be controllably grown to form an overlapping grid of CNTs. Such structure is desirable for certain applications. More particularly, FIGS. 7A-7B show an example of controllably growing a CNT 710 above the layer of parallel CNTs 610 resulting from the growth process of FIG. 6 described above. Thus, for instance, after controllably growing the parallel CNTs 610a on substrate 601, as described in FIG. 6 above, such substrate may be further processed to grow one or more CNTs, such as CNT 710 in the manner described further below in conjunction with FIGS. 7A-7B.

In the example of FIG. 7A, the parallel CNTs resulting from the growth process of FIG. 6 described above are shown as CNTs 610a-1, 610a-2, 610a-3, and 610a-4. Of course, any number of such parallel CNTs may be grown using the growth process of FIG. 6. Further, the substrate 601 has been processed to remove the topological structures 602₁-602ₙ and 605. For instance, if the topological structures of FIG. 6 are a deposited thin film layer, such layer may be etched away, or if the topological structures of FIG. 6 are trenches, such trenches may be filled in with deposition of material. Thereafter, topological structures 702₁ and 702₂ are formed on the substrate, and catalyst region 103 is deposited on the substrate. As shown in FIG. 7B, a layer 701 is deposited over the layer on which the CNTs 610a reside on substrate 601. For instance, CNTs 610a reside on substrate 601, and a layer 701 is deposited on which topological structures 702₁ and 702₂ are formed and on which catalyst region 103 is located. Further, in this example, layer 701 is etched away to form a cavity 705 at CNT 610a-2 such that CNT 710 grows within the growth path defined by topological structures 702₁ and 702₂ until it encounters the cavity 705 at CNT 610a-2. This encounter terminates growth of the CNT 710. Further, as shown in FIG. 7B, after growth of CNT 710, conductive material (e.g., gold) 707 is deposited to fill the cavity 705 to electrically couple CNT 710 to CNT 610a-2. Note that the material of layer 701 is an insulating material to insulate CNT 710 from CNTs 610a-3 and 610a-4.

While FIGS. 7A-7B show an example of controllably growing one CNT 710 oriented perpendicular to the CNTs 610, it should be recognized that more than one growth path may be defined, such as in FIG. 6, oriented perpendicular to the CNTs 610 to create a grid of overlapping CNTs. Further, each CNT of the second layer may be selectively electrically connected to a different one of the CNTs of the first layer in the manner described above for connecting CNT 710 to CNT 610a-2. Forming this type of grid of CNTs is desirable for various types of applications.

Turning to FIG. 8, an operational flow diagram according to one embodiment for controlling growth of nanotubes is shown. In operational block 801, the surface of a substrate is patterned to form a topological structure. As described above, in certain implementations, standard semiconductor fabrication techniques are used for such patterning. In operational block 802, a catalyst region for growing nanotubes is located on the substrate. In certain implementations, operations 801 and 802 may be reversed, wherein the catalyst region is first arranged on the substrate and the substrate is then patterned to form a topological structure. In operational block 803, the nanotube growth process is performed (e.g., CVD, PECVD, etc.) to grow nanotubes from the catalyst region along the substrate's surface. In block 804, the growth of the nanotubes is controlled by the topological structure. That is, the topological structure controls at least one of the length and orientation of the nanotubes. Thus, the topological structure provides a growth control structure that influences, during the growth process, at least one of length and orientation of the nanotubes.

In view of the above, topological structures are defined on the surface of a substrate for use in controlling nanotube growth instead of or in addition to use of other techniques. That is, physical contact by the nanotubes growing from a catalyst region along the surface of a substrate with topological structures control the length and/or orientation of the nanotubes. When referring to “controlling” the growth of nanotubes with topological structures herein, it should be appreciated that such topological structures may not fully control the nanotubes. For example, the nanotubes may initially grow in random directions from the catalyst region. Alternatively, some other element, such as an electric field, etc., may be used to control the direction of growth from the catalyst region. The topological structures provide control over the growth of nanotubes by influencing the growth (e.g., terminating the growth, re-directing the growth, etc.) of those nanotubes that encounter the topological structures.

The topological structures may be used in the above-described manner for controlling the growth of CNTs and other nanotube structures, such as boron nitride nanotubes and silicate-based nanotubes, that may be grown on a substrate surface in a manner similar to that described herein. Thus, for instance, while the above embodiments have been described for use in controlling the growth (e.g., the length and/or orientation) of CNTs, any other types of nanotube structures now known or later developed that may be grown from a catalyst region along the surface of a substrate may be controlled by using topological structures on the substrate in a like manner to that described above.

Further, while this concept has been described as being used for controlling the growth of nanotubes, it should be recognized that it can be readily adapted for use in controlling the growth of other nanostructures, particularly those having high aspect ratios, such as structures having transverse dimensions on the order of nanometers and the longitudinal dimension (length) on the order of 100 nanometers or more (e.g., hundreds of micrometers or even millimeters). For instance, topological structures may be used as described herein to control the growth of such nanostructures as nanotubes, nanofibers, nanoribbons, nanothreads, semiconductor nanowires, nanorods, nanobelts, nanosheets, nanorings, polymers, and biomolecules, as examples. Also, it should be recognized that the growth of nanotubes or other nanostructures is not limited to a particular growth process nor to a particular catalyst for such growth. Indeed, the catalyst used for growth may be seed particles or other forms of nucleating material layers arranged on the substrate, as examples. Thus, except where specified otherwise herein, the term “catalyst” broadly refers to any mechanism for growth of a nanostructure, including without limitation seed particles, etc.

What is claimed is:

1. A method comprising:
patterning a surface of a substrate to form a topological structure; and
growing nanostructures along the surface, wherein the topological structure controls the growth of the nanostructures.

2. The method of claim 1 wherein said topological structure controls at least one of the length and orientation of the nanostructures growing along the surface in at least one region of the substrate.

3. The method of claim 2 wherein physical contact of said nanostructures with said topological structure in said at least one region, during said growing, controls at least one of said length and orientation of said nanostructures.

4. The method of claim 3 wherein said topological structure comprises at least one of a blocking structure protruding from the surface of the substrate and a recess in the surface of the substrate.

5. The method of claim 1 further comprising:
locating a catalyst for growth of said nanostructures along on the surface of the substrate.

6. The method of claim 5 wherein said catalyst is located in relation to said topological structure to aid said topological structure in controlling the growth of the nanostructures.

7. The method of claim 6 wherein said catalyst is surrounded by said topological structure.

8. The method of claim 6 wherein the catalyst is centered in a growth field defined by the topological structure such that the catalyst is substantially equidistant from the growth field's perimeter in all directions.

9. The method of claim 1 wherein said patterning comprises:
forming two topological structures arranged to define a growth path.

10. The method of claim 9 wherein during said growing, any of said nanostructures growing within said growth path has its orientation controlled by said growth path.

11. The method of claim 1 wherein said patterning comprises forming topological structures arranged to define multiple group paths, further comprising:
orienting a first of said group paths in a first direction in one region of the substrate; and
orienting a second of said group paths in a different direction in a different region of the substrate.

12. The method of claim 1 wherein said patterning comprises:
defining said topological structure to control both orientation and length of ones of said nanostructures grown along the surface of the substrate.

13. The method of claim 1 wherein said patterning comprises:
defining said topological structure to control orientation of ones of the nanostructures relative to each other.

14. The method of claim 13 wherein the topological structure forms growth paths that are oriented relative to each other in a relative orientation desired for said ones of the nanostructures.

15. The method of claim 1 wherein said patterning comprises:
defining said topological structure to control spacing of ones of the nanostructures relative to each other.

16. The method of claim 15 wherein said patterning comprises:
defining said topological structure to form a plurality of growth paths that are spaced relative to each other by an amount of spacing desired for said ones of the nanostructures.

17. A system comprising:
a substrate having a surface that includes a topological structure; and
a catalyst for growth of nanostructures located on the substrate, wherein the topological structure controls the growth of the nanostructures along the substrate's surface.

18. The system of claim 17 wherein the topological structure is structured to control at least one of length and orientation of ones of the nanostructures.

19. The system of claim 17 wherein the topological structure is structured to control length and orientation of ones of the nanostructures grown along the substrate's surface.

20. The system of claim 17 wherein the topological structure comprises one of: a structure protruding from the surface of the substrate, a recess in the surface of the substrate, and a trench in the surface of the substrate.

21. The system of claim 17 wherein said catalyst is surrounded by said topological structure.

22. The system of claim 21 wherein the catalyst is centered in a growth field defined by the topological structure such that the catalyst is substantially equidistant from the growth field's perimeter in all directions along the substrate's surface.

23. The system of claim 17 wherein said topological structure defines a growth path on said substrate.

24. The system of claim 23 wherein said growth path controls the orientation of any of said nanostructures that grow in said growth path.

25. A method comprising:
patterning a substrate to form a topological structure;
locating on the substrate a catalyst for growing nanostructures; and
growing nanostructures from said catalyst along the substrate's surface, wherein physical contact by ones of the nanostructures with the topological structure controls at least one of the length and orientation of said ones of the nanostructures.

26. The method of claim 25 wherein said patterning comprises:
forming a topological structure on a region of the substrate for controlling at least one of the length and orientation of said ones of the nanostructures growing along the surface in the region of the substrate.

27. The method of claim 25 wherein said patterning comprises:
forming said topological structure to comprise one of: a blocking structure protruding from the surface of the substrate, a recess in the surface of the substrate, and a trench in the surface of the substrate.

28. The method of claim 25 wherein said arranging said catalyst comprises:
arranging said catalyst on said substrate in relation to said topological structure to aid said topological structure in controlling said at least one of the length and orientation of said ones of the nanostructures.

29. The method of claim 25 comprising:
physical contact by said ones of said nanostructures with said topological structure controls both orientation and length of said ones of said nanostructures.

30. The method of claim 25 further comprising:
during said growing, applying one of a force-field and fluid flow technique to influence the direction of growth of said nanostructures.

31. The method of claim 30 wherein said force-field technique comprises one of application of an electric field external to said substrate, application of an electric field local on said substrate, and application of a magnetic field; and wherein said fluid flow technique comprises one of directed gas, directed ion stream, and control of carbon gas density gradient.

32. The method of claim 25 further comprising:
utilizing a technique other than physical contact with said topological structure for influencing the direction of growth of said nanostructures.

33. A method comprising:
locating on a substrate at least one catalyst for growing nanotubes; and
adapting the terrain of a region of the substrate's surface to include a topological structure to control at least one of the length and orientation of nanotubes grown from the catalyst along the substrate's surface in said region.

34. The method of claim 33 wherein the topological structure mechanically controls the growth of the nanotubes.

35. The method of claim 33 wherein physical contact by the nanotubes with the topological structure controls the growth of the nanotubes.

36. A method comprising:
arranging on a substrate a catalyst for growing nanotubes;
patterning a first region of the substrate to form a first topological structure to control the growth of nanotubes from the catalyst in the first region;
patterning a second region of the substrate to form a second topological structure to control the growth of nanotubes from the catalyst in the second region; and
growing nanotubes from said catalyst, wherein physical contact with the first topological structure in said first region controls at least one of length and orientation of nanotubes growing in said first region and wherein physical contact with the second topological structure in said second region controls at least one of length and orientation of nanotubes growing in said second region.

37. The method of claim 36 further comprising:
said patterning said first region comprises forming said first topological structure defining a first growth path between structures on said substrate, said first growth path in said first region oriented in a first direction; and
said patterning said second region comprises forming said second topological structure defining a second growth path between structures on said substrate, said second growth path in said second region oriented in a direction different than said first direction.

38. A system comprising:
a first layer having at least a first nanotube grown thereon; and
a second layer having at least a second nanotube grown thereon, wherein a topological structure is included in at least one of said first and second layers for controlling, by physical contact, the growth of at least one of the first and second nanotubes.
